(19) United States
(12) Patent Application Publication
(10) Pub. No.: US 2022/0139815 A1
(43) Pub. Date: May 5, 2022

(54) SEMICONDUCTOR DEVICE AND METHOD MANUFACTURING THEREOF

(71) Applicant: ROHM CO., LTD., Kyoto (JP)

(72) Inventor: Satoshi KAGEYAMA, Kyoto (JP)

(21) Appl. No.: 17/511,274

(22) Filed: Oct. 26, 2021

(30) Foreign Application Priority Data
Oct. 29, 2020 (JP) 2020-181061

(51) Int. Cl. H01L 23/498; H01L 23/14; H01L 23/00; H01L 21/48; H01L 21/56

(52) U.S. Cl. CPC H01L 23/49827; H01L 23/49866; H01L 23/145; H01L 23/49811; H01L 2224/16225; H01L 21/486; H01L 24/81; H01L 21/56; H01L 24/16

(57) ABSTRACT

The present disclosure relates to a semiconductor device and a method manufacturing thereof. The object of the present disclosure is to simplify manufacturing steps of a semiconductor device. A semiconductor device of the present disclosure includes an organic film electrically insulative and penetrated by a through hole in a thickness direction, a conductive layer formed on the organic film and made of a copper (Cu)-based and titanium (Ti)-free alloy, a Cu wiring layer formed on the conductive layer, a semiconductor element mounted on the Cu wiring layer, a sealing resin sealing the semiconductor element, and an external terminal connected to the conductive layer. The conductive layer includes the exposed conductive portion exposed from the organic film by entering the through hole. The external terminal is in contact with the exposed conductive portion.

### TECHNICAL FIELD

The present disclosure relates to a semiconductor device and a manufacturing method thereof.

### DESCRIPTION OF THE PRIOR ART

Conventionally, an electronic component including a semiconductor element includes a substrate on which the semiconductor element is mounted, and a sealing resin covering the semiconductor element. For example, patent publication 1 discloses a semiconductor device including a wire having an external terminal on one surface and mounted with a semiconductor element on the other surface, and a sealing resin formed on the other surface of the wire to seal the semiconductor element.

### PRIOR ART DOCUMENT

### Patent Publication

[Patent document 1] Japan Patent Publication No. 2013-197263

### SUMMARY

### Problems to be Solved by the Disclosure

However, for the semiconductor device above, reducing the number of manufacturing steps of the semiconductor device and simplifying the existing manufacturing steps of the semiconductor device are desired.

It is an object of the present disclosure to provide a semiconductor device and a method manufacturing thereof capable of reducing manufacturing steps.

### Technical Means for Solving the Problem

To solve the problem above, a semiconductor device includes: an organic film, being electrically insulative and penetrated by a through hole in a thickness direction; a conductive layer, formed on the organic film and made of a copper (Cu)-based and titanium (Ti)-free alloy; a Cu wiring layer, formed on the conductive layer; a semiconductor element, mounted on the Cu wiring layer; a sealing resin, sealing the semiconductor element; and an external terminal, connected to the conductive layer, wherein the conductive layer includes an exposed conductive portion entering the through hole and exposed from the organic film, and the external terminal is in contact with the exposed conductive portion.

According to the configuration, after forming the organic film on the sacrificial film made of Ti and forming the conductive layer on the organic film, since the conductive layer is Ti-free, deleting of the conductive layer together with the sacrificial film can be inhibited when the sacrificial film is deleted from the organic film. Thus, an intermediary for preventing the deleting of the conductive layer while the sacrificial film is deleted is not needed between the sacrificial film and the conductive layer. Therefore, the step of forming the intermediary can be omitted to simplify the manufacturing steps of the semiconductor device.

To solve the problem above, a manufacturing method for a semiconductor device includes: a preparatory process, forming a temporary fixing layer on a support substrate and forming a sacrificial film made of Ti on the temporary fixing layer; an organic film forming process, forming an electrically insulative organic film in which a through hole penetrates in a thickness direction on the sacrificial film; a conductive layer forming process, forming a conductive layer made of a copper (Cu)-based and titanium (Ti)-free alloy on each of the organic film and the sacrificial film exposed from the through hole; a wiring layer forming process, forming a Cu wiring layer on the conductive layer; an element mounting process, electrically connecting a semiconductor element to the Cu wiring layer; a resin layer forming process, forming a resin layer to seal the semiconductor element; a first deleting process, deleting the support substrate and the temporary fixing layer; and a second deleting process, deleting the sacrificial film, wherein in the conductive layer forming process, the conductive layer enters the through hole and contacts the sacrificial film.

According to the configuration, after forming the organic film on the sacrificial film made of Ti and forming the conductive layer on the organic film, since the conductive layer is Ti-free, deleting of the conductive layer together with the sacrificial film can be inhibited when the sacrificial film is deleted from the organic film. Thus, an intermediary for preventing the deleting of the conductive layer while the sacrificial film is deleted is not needed between the sacrificial film and the conductive layer. Therefore, the step of forming the intermediary can be omitted to simplify the manufacturing steps of the semiconductor device.

### Effects of the Disclosure

Manufacturing steps can be simplified according to the semiconductor device and the method manufacturing thereof.

### BRIEF DESCRIPTION OF THE DRAWINGS

FIG. 1 is a section diagram of a section structure of a semiconductor device according to an embodiment;

FIG. 2 is a rear view of a semiconductor device according to an embodiment;

FIG. 3 is an enlarged partial view of the semiconductor device in FIG. 1;

FIG. 4 is an illustration diagram of a manufacturing step of a manufacturing method for a semiconductor device according to an embodiment;

FIG. 5 is an illustration diagram of a manufacturing step of a manufacturing method for a semiconductor device;

FIG. 6 is an illustration diagram of a manufacturing step of a manufacturing method for a semiconductor device;

FIG. 7 is an illustration diagram of a manufacturing step of a manufacturing method for a semiconductor device;

FIG. 8 is an illustration diagram of a manufacturing step of a manufacturing method for a semiconductor device;

FIG. 9 is an illustration diagram of a manufacturing step of a manufacturing method for a semiconductor device;

FIG. 10 is an illustration diagram of a manufacturing step of a manufacturing method for a semiconductor device;

FIG. 11 is an illustration diagram of a manufacturing step of a manufacturing method for a semiconductor device;

FIG. 12 is an illustration diagram of a manufacturing step of a manufacturing method for a semiconductor device;

FIG. 13 is an illustration diagram of a manufacturing step of a manufacturing method for a semiconductor device;

FIG. 14 is an illustration diagram of a manufacturing step of a manufacturing method for a semiconductor device;

FIG. 15 is an illustration diagram of a manufacturing step of a manufacturing method for a semiconductor device;

FIG. 16 is an illustration diagram of a manufacturing step of a manufacturing method for a semiconductor device; and

FIG. 17 is an enlarged partial section diagram of a section structure of a semiconductor device of a comparison example.

### DETAILED DESCRIPTION OF THE EMBODIMENTS

Details of the embodiments with respect to a semiconductor device are given with the accompanying drawings below. The embodiments below are examples for illustrating specific configurations of methods based on technical concepts, and materials, shapes, structures, configurations and sizes of the constituting components are not limited to the description below. Various modifications may be made to the embodiments below. (Structure of the semiconductor device)

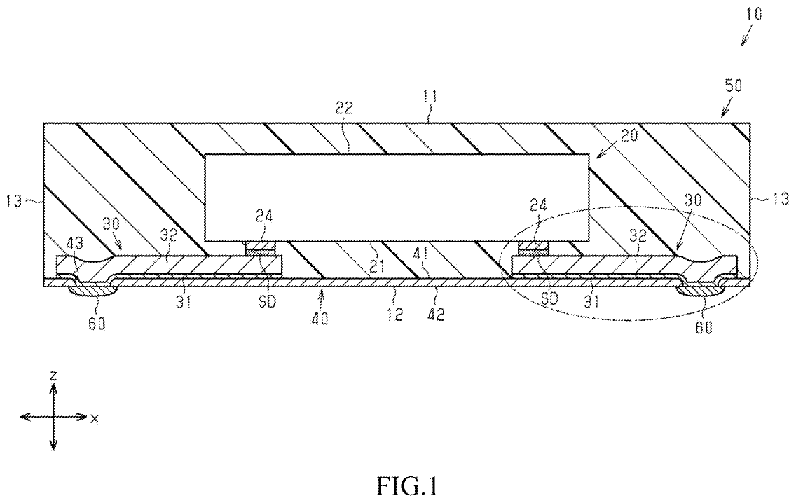

Referring to FIG. 1 to FIG. 3, the configuration of a semiconductor device 10 according to an embodiment is described below.

The semiconductor device 10 is a device that is surface-mounted on a wiring substrate of various electronic devices. Herein, for illustration purposes, the thickness direction of the semiconductor device 10 is set as the z direction, the direction orthogonal to the thickness direction z and along one side of the semiconductor device 10 is set as the x direction, and the direction orthogonal to both the x direction and the z direction is set as the y direction.

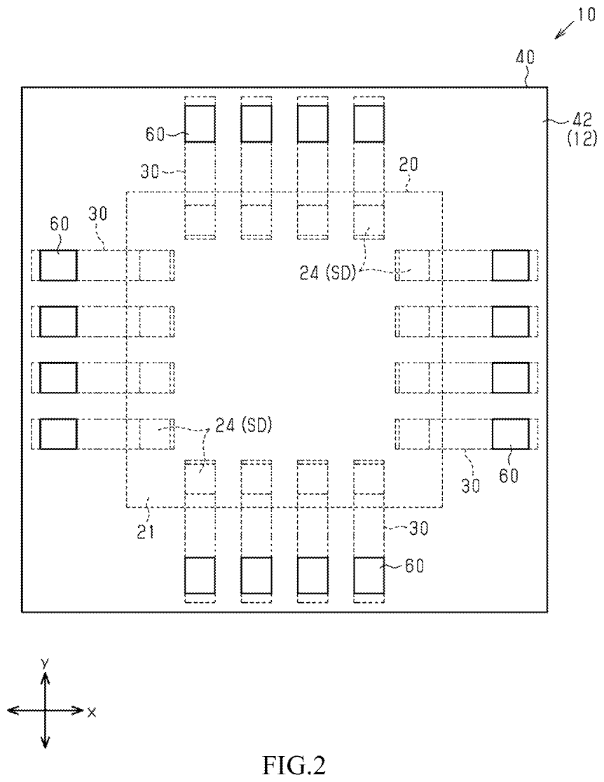

As shown in FIG. 1 and FIG. 2, the length of the semiconductor device 10 is shaped as a rectangular plate with the length in the z direction being less than the lengths in the x direction and the y direction. In this embodiment, when observed in the z direction, the semiconductor device 10 is shaped as a square. The semiconductor device 10 has a device main surface 11 and a device back surface 12 facing opposite sides from each other in the z direction, and four device side surfaces 13 facing the x direction or the y direction between the device main surface 11 and the device back surface 12 in the z direction.

The semiconductor device 10 includes a semiconductor element 20, a wire 30 connected to the semiconductor element 20, an organic film 40 supporting the wire 30, a sealing resin 50 sealing the semiconductor element 20 and the wire 30, and an external terminal 60 connected to the wire 30. The semiconductor device 10 is a chip-size package that is packaged in a wafer state, that is, a semiconductor device in a FOWLP (Fan Out Wafer Level Package) with external terminal 60 arranged outside the semiconductor element 20.

The organic film 40 forms the device back surface 12, and, between two end portions of each device side surface 13 in the z direction, an end portion close to the device back surface 12. The organic film 40 is made of, for example, a photosensitive organic film, and is made of polyamide (PI) in this embodiment. The organic film 40 is not limited to PI, and phenolic resin or polybenzoxazole (PBO) may also be used.

The organic film 40 has a film main surface 41 and a film back surface 42 facing opposite sides from each other in a thickness direction (z direction). In this embodiment, the z direction may be said as the thickness direction of the organic film 40. The film main surface 40 faces the same side as the device main surface 11, and the film back surface 42 faces the same side as the device back surface 12. In this embodiment, the film back surface 42 forms the device back surface 12.

The organic film 40 has a plurality of through holes 43 in the thickness direction (z direction). The through holes 43 are arranged outside relative to the semiconductor element 20 in the x direction or in the y direction, that is, closer to the device side surfaces 13 with respect to the semiconductor element 20.

As shown in FIG. 1, a plurality of wires 30 are formed on the organic film 40. As shown in FIG. 2, when observed in the z direction, the wires 30 extend in the x direction or in they direction. When observed in the z direction, each of the wires 30 has an inner portion overlapping with the semiconductor element 20, and an outer portion extending outside relative to the semiconductor element 20. A part of the outer portion of each of the wires 30 enters the through hole 43.

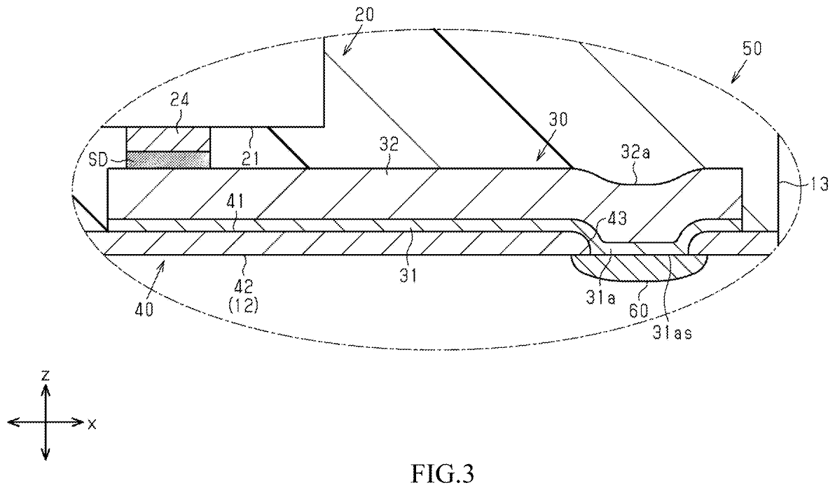

As shown in FIG. 3, each of the wires 30 includes a conductive layer 31 made of a copper (Cu)-based and titanium (Ti)-free alloy, and a Cu wiring layer 32 formed on the conductive layer 31. Each of the wires 30 is formed of a layered structure including the conductive layer 31 and the Cu wiring layer 32.

The conductive layer 31 is made of an alloy containing Cu as a main component and any of aluminum (Al), magnesium (Mg) and manganese (Mn). In this embodiment, the conductive layer 31 has Cu as the main component and is made of an Al alloy, i.e., CuAlx.

The conductive layer 31 is formed to be in contact with the film main surface 41 of the organic film 40. In other words, the conductive layer 31 is formed on the film main surface 41. Moreover, the conductive layer 31 includes an exposed conductive portion 31a exposed from the organic film 40 by entering the through hole 43. More specifically, the exposed conductive portion 31a is exposed from the film back surface 42 of the organic film 40. The exposed conductive portion 31a is arranged outside relative to the semiconductor element 20 in a direction orthogonal to the z direction (in this embodiment, in the x direction and the y direction). As shown in FIG. 3, the exposed conductive portion 31a becomes a recessed shape recessing from the film main surface 41 to the film back surface 42 of the organic film 40. In this embodiment, an exposed surface 31as of the exposed conductive portion 31a is flush with the film back surface 42 (the device back surface 12). Herein, when observed in the z direction, the exposed surface 31as is, in the exposed conductive portion 31a, a portion non-overlapping with the organic film 40 and facing the same side as the film back surface 42. The thickness (the length in the z direction) of the conductive layer 31 is, for example, between 400 nanometers (nm) and 600 nm.

The Cu wiring layer 32 includes Cu. When observed in the z direction, the Cu wiring layer 32 is formed to cover the entire conductive layer 31. The thickness (the length in the z direction) of the Cu wiring layer 32 is, for example, between 3 μm and 20 μm, and varies according to the purpose of the semiconductor device 10. The thickness of the Cu wiring layer 31 is set according to, for example, the value of the maximum current supplied to the semiconductor device 10. The thickness of the Cu wiring layer 31 is set to increase as the maximum current supplied to the semiconductor device 10 increases. As such, the thickness of the Cu wiring layer 32 is thick enough compared to the thickness of the conductive layer 31.

A recessed portion 32a is formed on a portion of the Cu wiring layer 32 formed on the exposed conductive portion 31a, that is, a portion of the Cu wiring layer 32 entering the through hole 43 of the organic film 40. The recessed portion 32a is recessed toward the film back surface 42.

As shown in FIG. 1, the semiconductor element 20 is mounted on the Cu wiring layer 32. The length of the semiconductor element 20 is shaped as a rectangular plate with the length in the z direction being less than the lengths in the x direction and the y direction. As shown in FIG. 2, in this embodiment, when observed in the z direction, the semiconductor element 20 is shaped as a square. As shown in FIG. 1, the semiconductor element 20 has an element main surface 21 and an element back surface 22 facing opposite sides from each other in its thickness direction (the z direction). The semiconductor element 20 is arranged with the element main surface 40 facing the same side as the device back surface 12, and the element back surface 22 facing the same side as the device main surface 11. The thickness (the length between the element main surface 21 and the element back surface 22 in the z direction) of the semiconductor element 20 is, for example, 100 μm.

The semiconductor element 20 is, for example, an integrated circuit (IC) such as a large scale integration (LSI). Moreover, the semiconductor element 20 may also be a discrete semiconductor element, for example, a voltage control element such as a low-drop out (LDO), an amplification element such as an operational amplifier (OA), a diode or various sensors. In case of an LSI, the element main surface 21 is a surface on which a constituting component for performing the function of the semiconductor element 20 is formed. Moreover, the semiconductor element 20 is not limited to having multiple constituting components formed therein, and may be configured as an element having one single constituting component formed therein or an element having constituting components formed on a substrate outside the semiconductor, such as a chip capacitor or a chip inductor.

The semiconductor element 20 includes a plurality of element electrodes 24. As shown in FIG. 2, the plurality of element electrodes 24 are arranged on an outer peripheral portion in the element main surface 21 of the semiconductor element 20. As shown in FIG. 1, each of the element electrodes 24 protrudes from the element main surface 21 toward the device back surface 12. Each of the element electrodes 24 is bonded to the Cu wiring layer 32 by a conductive bonding material, for example, a solder layer SD. The solder layer SD is a solder block formed at, for example, a front end surface of each of the element electrodes 24. The solder layer SD is formed by plating a metal on each of the element electrodes 24 and depositing an alloy containing tin (Sn).

In this embodiment, each of the element electrodes 24 is bonded at a portion different from the recessed portion 32a in the Cu wiring layer 32, that is, a flat portion in the Cu wiring layer 32.

The sealing resin 50 is formed to be in contact with the film main surface 41 of the organic film 40 in the z direction. The sealing resin 50 forms the device main surface 11 and the device side surfaces 13. The sealing resin 50 forming the device side surface 13 is flush with the organic film 40 forming the device side surface 13. The sealing resin 50 includes an insulative material, for example, including a black epoxy resin.

As shown in FIG. 3, an external terminal 60 is formed at the exposed conductive portion 31a of conductive layer 31. The external terminal 60 is in contact with the exposed conductive portion 31a. When observed in the z direction, the external terminal 60 is formed to cover the entire exposed conductive portion 31a. The external terminal 60 becomes an external connection terminal of the semiconductor device 10. The external terminal 60 is formed by, for example, a plurality of metal layers deposited on one another. The metal layers may be, for example, a nickel (Ni) layer, a palladium (Pd) layer and a gold (Au) layer. In addition, the material of the external terminal 60 is not limited, and may be formed by, for example, depositing a Ni layer and a Au layer, or Sn.

### (Manufacturing Method for a Semiconductor Device)

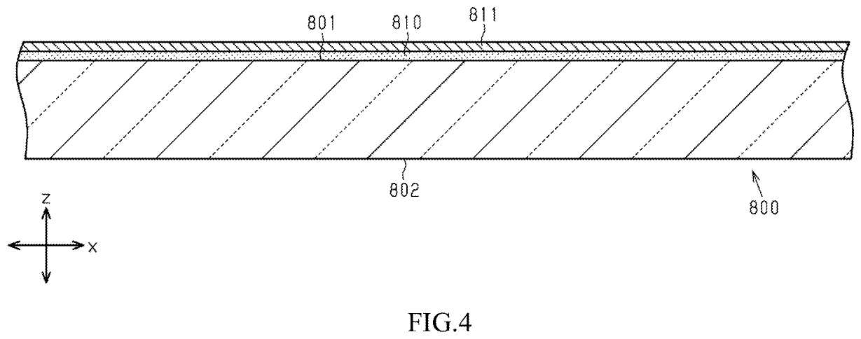

Referring to FIG. 4 to FIG. 16, a manufacturing method for the semiconductor device 10 according to this embodiment is described below.

The manufacturing method for the semiconductor device 10 includes a preparatory process, an organic film forming process, a wire forming process, an element mounting process, a resin layer forming process, a first deleting process, a second deleting process, an external terminal forming process, and a cutting process. The steps are described in detail in the description below.

As shown in FIG. 4, in the preparatory process, the substrate main surface 801 and the substrate back surface 802 facing opposite sides from each other in the thickness direction (the z direction) are prepared, for example, a support substrate 800 containing glass. Next, a temporary fixing layer 810 is formed on the substrate main surface 801 of the support substrate 800. After component formed on the temporary fixing layer 810 is fixed with the support layer 800, the temporary fixing layer 810 is a layer that can peel off the support layer 800 from the component. The temporary layer 810 is, for example, a temporary adhesive including a resin composition containing a resin component thermally decomposable by heating. Such resin composition is, for example, a polycarbonate resin, a polyester resin, a polyamide resin, a polyimide resin, a polyether resin, a polyurethane resin, acrylic resin, a polyolefin resin, and one or a combination of two or more of these resins may be used. The temporary fixing layer 810 is formed, for example, across the entire substrate main surface 801.

Next, a sacrificial layer 811 is formed on the temporary fixing layer 810. The sacrificial layer 811 is made of, for example, Ti. The sacrificial layer 811 is formed by, for example, sputtering. The sacrificial layer 811 is formed, for example, across an entire upper surface of the temporary fixing layer 810 facing the same side as the substrate main surface 801. The sacrificial layer 811 has a thickness of, for example, approximately 300 μm.

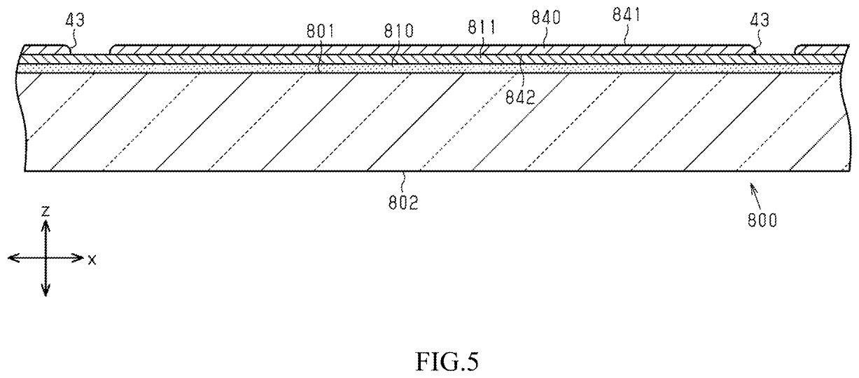

As shown in FIG. 5, in the organic film forming process, an organic film 840 is formed on the sacrificial layer 811. The organic film 840 has a film main surface 841 and a film back surface 842 facing opposite sides from each other in the thickness direction (the z direction). The film main surface 841 faces the same side as the substrate main surface 801, and the film back surface 842 faces the same side as the substrate back surface 802. The film back surface 842 is in contact with the sacrificial layer 811.

The thickness of the organic film 840 (the thickness of the organic film 840 in the z direction) is more than the thickness of the sacrificial layer 811 (the thickness of the sacrificial layer 811 in the z direction). The organic film 840 is made of photosensitive PI, and is formed by, for example, spin coating. At this point, a through hole 43 is formed at the organic film 840. The through hole 43 penetrates the organic film 840 in the thickness direction 840 (the z direction). Thus, the sacrificial layer 811 is exposed from the through hole 43.

The wire forming layer includes a conductive layer forming process, a wiring layer forming process and a conductive layer removal process. The wiring layer forming process is performed after the conductive layer forming step. The conductive layer forming process is performed after the wiring layer forming step.

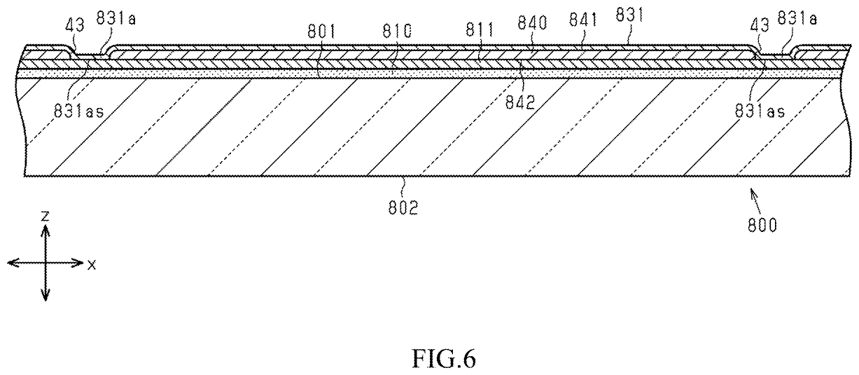

As shown in FIG. 6, in the conductive layer forming process, a conductive layer 831 (a seed layer) that becomes the conductive layer 31 (a substrate layer) is formed on the film main surface 841 of the organic film 840. The conductive layer 831 is a sputtered layer formed by, for example, sputtering. The conductive layer 831 is made of a Cu-based and Ti-free alloy. More specifically, the conductive layer 831 is made of an alloy containing Cu as a main component and any Al, Mg and Mn. In this embodiment, the conductive layer 831 has Cu as the main component and is made of an Al alloy, i.e., CuAlx. The thickness of the conductive layer is preferably between 400 nm and 600 nm. In addition to being formed on the organic film 840, the conductive layer 831 is also formed on each of an inner surface of the organic film 840 forming the through hole 43 and the sacrificial layer 811 exposed by the through hole 43. Thus, the conductive layer 831 has an exposed conductive portion 831a including a portion formed on the inner surface of the through hole 43 and a portion formed on the sacrificial film 811. Thus, the exposed conductive portion 831a is in contact with the sacrificial layer 811. A surface in the exposed conductive portion 831a contacting with the sacrificial layer 811 forms an exposed surface 831as. Because both the exposed surface 831as and the film back surface 842 of the organic film 840 are formed on the sacrificial layer 811, the exposed surface 831as is flush with the film back surface 842.

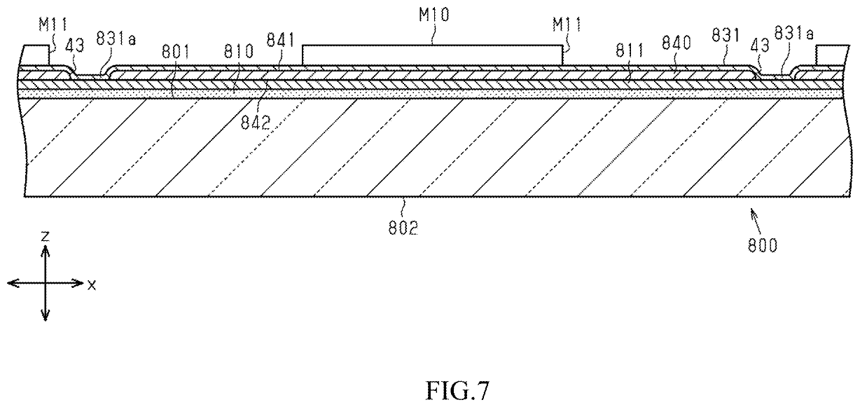

In the wiring layer forming process, as shown in FIG.7, a mask layer M10 is first formed on the conductive layer 831. The mask layer M10 is formed by photolithography using, for example, a photosensitive resist layer. More specifically, the photosensitive resist layer is formed on the conductive layer 831. The resist layer is formed by, for example, spray coating a liquid photoresist. Moreover, a film photoresist may also be used. The mask layer M10 having an opening M11 at a specific position is formed by performing exposure and development on a resist layer. The opening M11 is formed to expose the conductive layer 831 in the region corresponding to the shape of the Cu wiring layer 32 shown in FIG. 1 and FIG. 2.

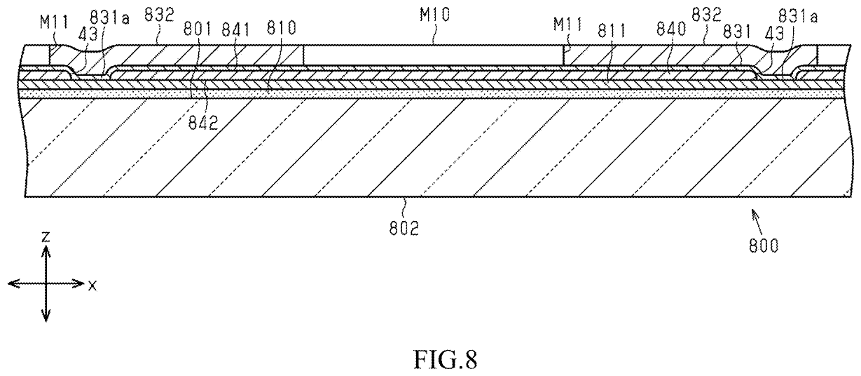

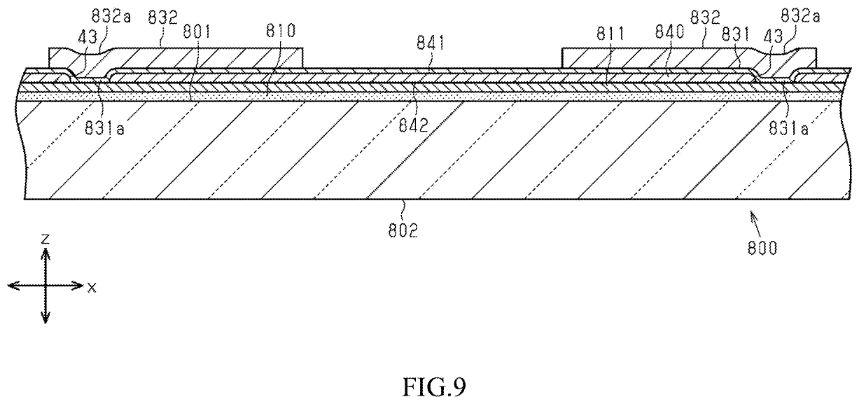

Next, as shown in FIG. 8, a wiring layer 832 (a plating layer) that becomes the Cu wiring layer 32 is formed on the conductive layer 831 exposed from the opening M11 of the mask layer M10. The Cu wiring layer 832 is formed by, for example, electroplating. In electroplating, the conductive layer 831 is used as a conductive path, and Cu is deposited as a plating metal on the conductive layer 831 to form the Cu wiring layer 832. A recessed portion 832a corresponding to the recessed portion 32a of the Cu wiring layer 32 is formed by a portion of the Cu wiring layer 832 covering the exposed conductive portion 831a. Next, as shown in FIG. 9, the mask layer M10 in FIG. 8 is removed. Accordingly, the conductive layer 831 not covered by the Cu wiring layer 832 is exposed.

In the conductive layer removal process, the conductive layer 31 is formed by removing the conductive layer 831 not covered by the Cu wiring layer 832. In this embodiment, the Cu wiring layer 832 itself is used as a mask layer to remove the conductive layer 831.

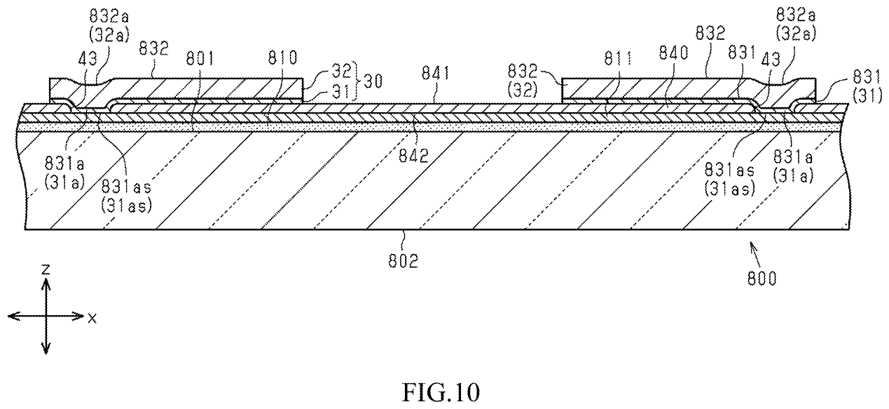

More specifically, as shown in FIG. 10, the conductive layer 831 exposed from the Cu wiring layer 832 is removed by, for example, wet etching using an etching liquid. During wet etching, the process is performed by removing the portion that becomes the wire 30 in FIG. 1 and FIG. 2, without leaving any residual conductive layer 831 on the organic film 840. Accordingly, the wire 30 is formed. Moreover, the film main surface 841 of the organic film 840, apart from the portion that becomes the wire 30, is exposed.

In the element mounting process, the semiconductor element 20 is mounted to the wire 30.

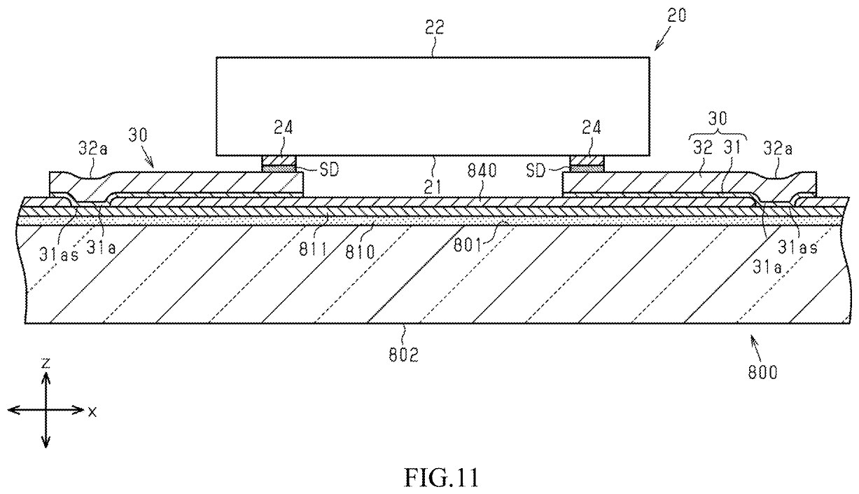

More specifically, as shown in FIG. 11, a solder layer SD is formed on a front end surface of each of the element electrodes 24 of the semiconductor element 20. The semiconductor element 20 is melted by a reflow process before the wiring 30 is mounted, and a roughened surface of the solder layer SD is smoothed. By the smoothing, air pores are unlikely caused when the solder layer SD is bonded to the wire 30.

Next, each of the element electrodes 24 (the solder layer 24) of the semiconductor element 20 is bonded to a portion different from the recessed portion 32a in the Cu wiring layer 32 of the wire 30. That is to say, each of the element electrodes 24 is bonded to a flat portion in the Cu wiring layer 32.

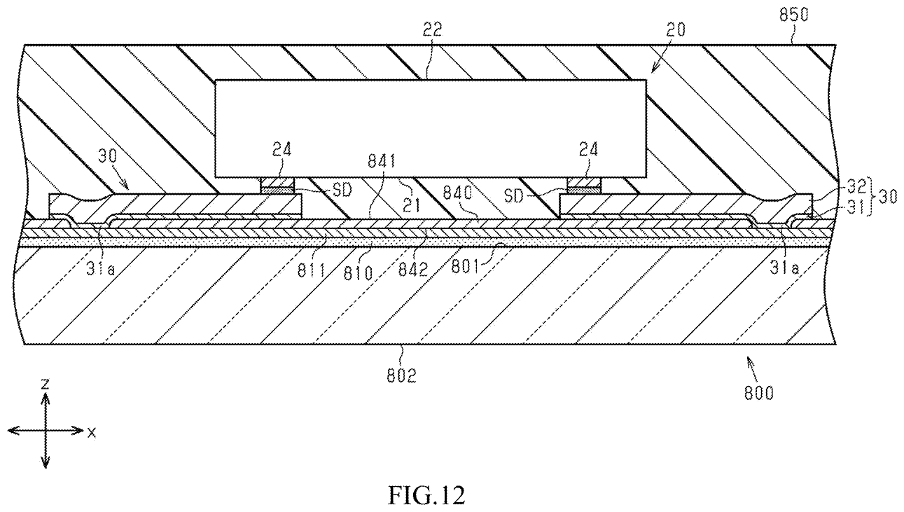

As shown in FIG. 12, in the resin layer forming process, a resin layer 850 that becomes the sealing resin 50 sealing the semiconductor element 20 is formed. The resin layer 850 includes an insulative material, for example, including a black epoxy resin. The resin layer 850 covers the entire semiconductor element 20, and covers the element electrodes 24 and the solder layer SD. In addition, the resin layer 850 is in contact with a side surface of the conductive layer 31 orthogonal to the z direction, the Cu wiring layer 32 and the film main surface 841 of the organic film 840.

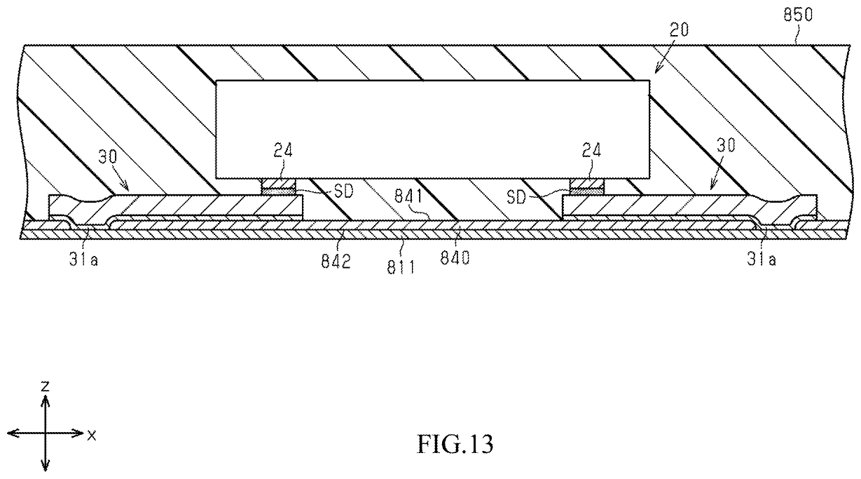

As shown in FIG. 13, in the first deleting process, the temporary fixing layer 810 and the supporting substrate 800 are peeled off from the sacrificial film 811. In an example, first of all, the bonding strength between the temporary fixing layer 810 and the sacrificial layer 811 is reduced by illuminating a laser upon or heating the temporary fixing layer 810. Next, the temporary fixing layer 810 is peeled from the sacrificial layer 811.

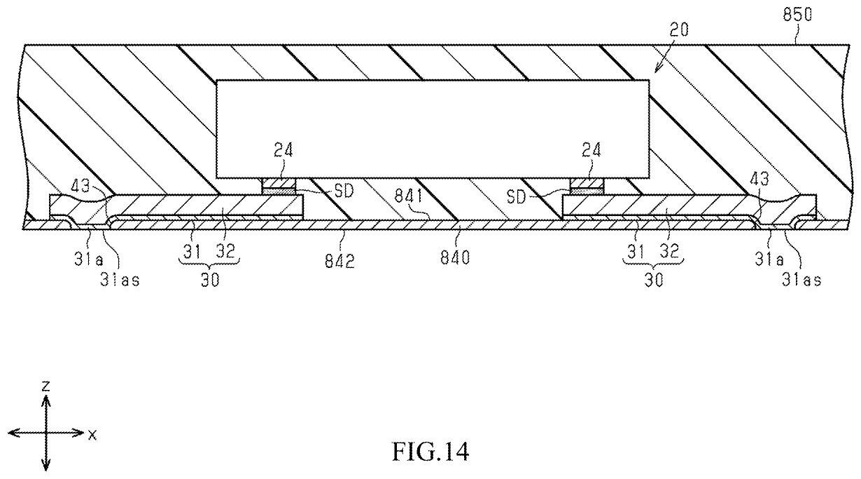

As shown in FIG. 14, in the second deleting process, the sacrificial film 811 is removed. More specifically, the sacrificial layer 811 is removed by, for example, wet etching using an etching liquid. Accordingly, the conductive layer 31 formed on the film back surface 842 of the organic film 840 and in the through hole 43 of the organic film 840 is exposed (the exposed surface 31as of the exposed conductive portion 31a) in the z direction.

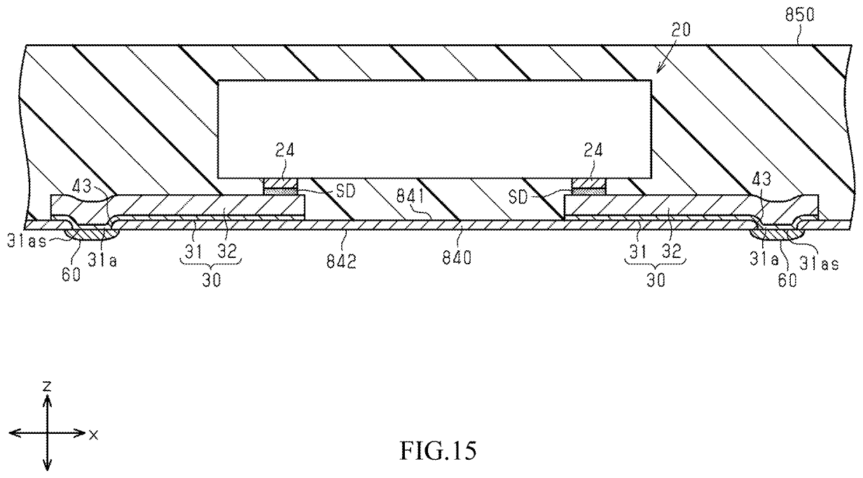

As shown in FIG. 15, in the external terminal mounting process, a plurality of external terminals 60 are formed. The external terminals 60 are formed to be in contact with the conductive layer 831 (the exposed conductive portion 31a) in the through hole 43 of the organic film 840. The external terminals 60 are formed by, for example, electroless plating. The external terminal 60 is formed by, for example, a plurality of metal layers deposited on one another. The metal layers may be, for example, a Ni layer, a Pd layer and an Au layer. That is to say, the external terminals 60 are formed by forming the Ni layer on the exposed conductive layer 831, forming the Pd layer on the Ni layer and forming the Au layer on the Pd layer.

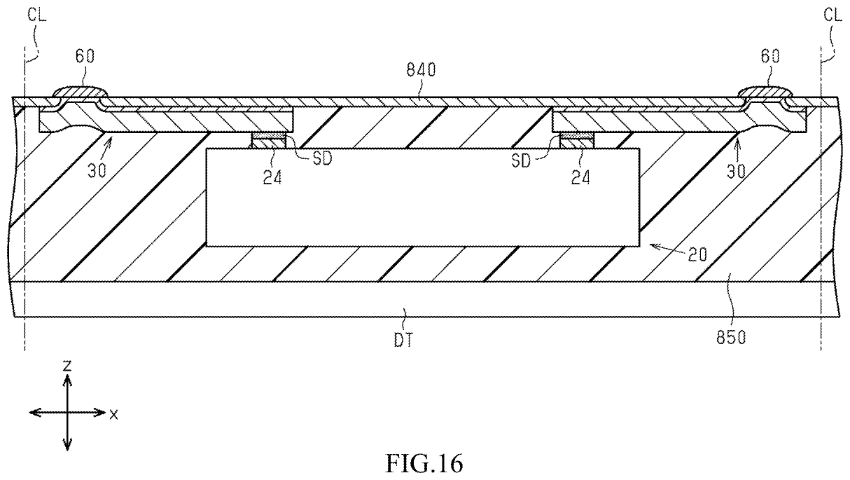

In the cutting process, as shown in FIG. 16, a dissecting adhesive tape DT is adhered on the resin layer 850, and the organic film 840 and the resin layer 850 are cut along the cutting lines CL using, for example, a cutting blade. Accordingly, the organic film 840 forms the organic film 40, and the resin layer 850 forms the sealing resin 50. The semiconductor device 10 is manufactured by the steps above.

### (Effects)

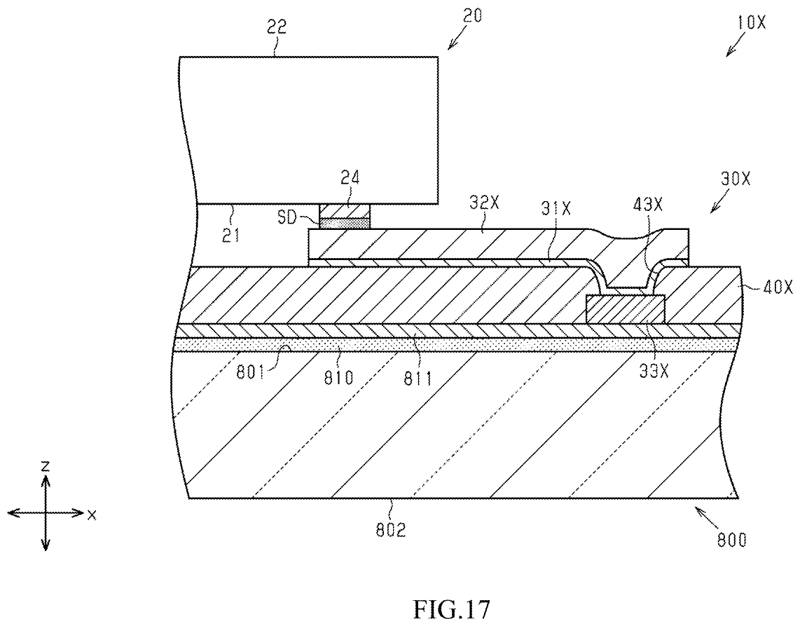

Referring to FIG. 17, effects of the semiconductor device 10 according to the embodiment are described below. FIG. 17 shows a partial section structure of a semiconductor device 10X during a manufacturing process of the semiconductor device 10X of a comparison example.

As shown in FIG. 17, compared to the semiconductor device 10 of the embodiment, the configuration of a wire in the semiconductor device 10X in different. More specifically, the wire 30X of the semiconductor device 10X includes a Ti layer 31X formed on an organic film 40X, a main surface side Cu wiring layer 32X formed on the Ti layer 31X, and a back surface side wiring layer 33X connected to the Ti layer 31X. Similar to the conductive layer 31 of the semiconductor device 10, the Ti layer 31X enters a through hole 43X of the organic film 40X. The back surface side Cu wiring layer 33X intermediates between the sacrificial layer 811 and the Ti layer 31X entering the through hole 43X of the organic film 40X. That is to say, the back surface side Cu wiring layer 33X is arranged correspondingly to the through hole 43X of the organic film 40X.

Reasons that the organic film 40X is not directly formed on the main surface side Cu wiring layer 32X are as follows. The adhesion between the organic film 40X and the main surface side Cu wiring layer 32X is unsatisfactory, and when the organic film 40X is directly formed on the main surface side Cu wiring layer 32X, there is a concern that the main surface side Cu wiring layer 32X may become peeled off from the organic film 40X. Therefore, by intermediating Ti that provides better adhesion between the organic film 40X and Cu between the organic film 40X and the main surface side Cu wiring layer 32X, the main surface side Cu wiring layer 32X is inhibited from peeling from the organic film 40X.

Next, the main reason for providing the back surface side Cu wiring layer 33X is that, there is a concern that the Ti layer 31X may be removed altogether with the sacrificial layer 811 in the process of removing the sacrificial layer 811 if the sacrificial layer 811 including Ti is in contact with the Ti layer 31X. If the Ti layer 31X is removed, as described above, there is a concern that the main surface side Cu wiring layer 32X may be peeled off from the organic film 840.

Thus, the sacrificial layer 811 needs to be separated from the Ti layer 31X. That is to say, an intermediary other than a Ti-containing material is needed between the sacrificial layer 811 and the Ti layer 31X. On the other hand, because the Ti layer 31X entering the through hole 43X of the organic film 40X is electrically connected to an external terminal (not shown), the intermediary is preferably an electrical conductor. Therefore, the semiconductor device 10X has the back surface side Cu wiring layer 33X as the intermediary. The back surface side Cu wiring layer 33X is exposed from the organic film 40X in the z direction. An external terminal is formed at an exposed portion of the back surface side Cu wiring layer 33X.

The manufacturing method for the semiconductor device 10X of the comparison example includes: a first wiring layer forming process, forming the back surface side Cu wiring layer 33X on the sacrificial layer 811; an organic film forming process, forming the organic film 40X on the sacrificial layer 811 to cover the back surface side Cu wiring layer 33X; a process of forming the through hole 43X on the organic film 40X; a process of forming the Ti layer 31X on the organic film 40X; a second wiring layer forming process, forming the main surface side Cu wiring layer 32X on the Ti layer 31X; and a Ti layer removal process, removing a portion of the Ti layer 31X on which the main surface side Cu wiring layer 32X is not layered.

As such, in the manufacturing method for the semiconductor device 10X of the comparison example, compared to the manufacturing method for the semiconductor device 10 of the embodiment, an additional first wiring layer forming process needs to be implemented.

In the first wiring layer forming process, first of all, a Cu wiring layer is formed across the entire sacrificial layer 811. Next, a mask layer is formed on the Cu wiring layer. The mask layer is formed by, for example, photolithography using a photosensitive resist layer. More specifically, the photosensitive resist layer is formed on the Cu wiring layer. The resist layer is formed by, for example, spray coating a liquid photoresist. Moreover, a film photoresist may also be used. The resist layer having an opening at a specific position is formed by performing exposure and development on a resist layer. The opening is formed by exposing the Cu wiring layer other than a portion that forms the back surface side Cu wiring layer 33X.

Next, the Cu wiring layer exposed from the opening is removed by, for example, wet etching using an etching liquid. During wet etching, the process is performed by removing the portion that becomes the back surface side Cu wiring layer 33X, without leaving any residual Cu wiring layer on the sacrificial layer 811. Accordingly, the back surface side Cu wiring layer 33X is formed. Moreover, the sacrificial film 811 is exposed at a portion other than the back surface side Cu wiring layer 33X. Next, the mask layer is removed.

On the other hand, in the semiconductor device 10 of this embodiment, because the conductive layer 31 contacting the sacrificial layer 811 is made of a Cu-based and Ti-free alloy, which is CuAlx in this embodiment, the conductive layer 31 is inhibited from being deleted while the sacrificial layer 811 is removed. In addition, the conductive layer made of CuAlx and the organic film 40 have better adhesion. Thus, without needing the additional back surface side Cu wiring layer 33X, the Cu wiring layer 32 is inhibited from peeling off from the organic film 40.

As such, the first wiring layer forming process including multiple steps is omitted from the semiconductor device 10 of this embodiment, the manufacturing method for the semiconductor device 10 is more simplified compared to the semiconductor device 10X of the comparison example.

### (Results)

The semiconductor device 10 of the embodiment achieves the following effects.

(1) The semiconductor device 10 includes the organic film 40 electrically insulative and penetrated by the through hole 43 in the z direction, the conductive layer 31 formed on the organic film 40 and made of a Cu-based and Ti-free alloy, the Cu wiring layer 32 formed on the conductive layer 31, the semiconductor device 20 mounted on the Cu wiring layer 32, the sealing resin 50 sealing the semiconductor element 20, and the external terminal 60 connected to the conductive layer 31. The conductive layer 31 includes the exposed conductive portion 31a exposed from the organic film 40 by entering the through hole 43. The external terminal 60 is in contact with the exposed conductive portion 31a.

According to the configuration, after forming the organic film 840 on the sacrificial film 811 made of Ti and forming the conductive layer 831 on the organic film 840, since the conductive layer 831is Ti-free, deleting of the conductive layer 831 together with the sacrificial layer 811 can be inhibited when the sacrificial film 811 is deleted from the organic film 840. Thus, unlike the semiconductor device 10X of the comparison example, an intermediary (the back surface side Cu wiring layer 33X of the semiconductor device 10X) needed in the comparison example for preventing the deleting of the conductive layer 831 (31) while the sacrificial layer 811 is deleted is not needed between the sacrificial film 811 and the conductive layer 831 (31). Therefore, the step of forming the intermediary (the first wiring layer forming process in the manufacturing method for the semiconductor device 10) can be omitted to simplify the manufacturing steps of the semiconductor device 10.

Moreover, since the conductive layer 31 is made of a Cu-based alloy, a conventionally known method may be used when forming the external terminal 60 contacting the exposed conductive portion 31a. That is to say, in the process of forming the external terminal 60, a conventionally known device may be used. As such, according to the semiconductor device 10, since manufacturing steps can be simplified and a conventionally known device may be used, manufacturing costs of the semiconductor device 10 are reduced.

(2) The conductive layer 31 is made of an alloy containing Cu as a main component and any of Al, Mg and Mn. According to the configuration, the adhesion between the conductive layer 31 and the organic film 40 is increased. Thus, the wire 30 can be inhibited from peeling off from the organic film 40.

(3) The manufacturing method for a semiconductor device includes: a preparatory process, forming the temporary fixing layer 810 on the support substrate 800 and forming the sacrificial film 811 made of Ti on the temporary fixing layer 810; an organic film forming process, forming the electrically insulative organic film 840 in which the through hole 43 penetrates in the z direction on the sacrificial film 811; a conductive layer forming process, forming the conductive layer 831 made of a Cu-based and Ti-free alloy on the organic film 840; a wiring layer forming process, forming the Cu wiring layer 832 on the conductive layer 831; an element mounting process, electrically connecting the semiconductor element 20 to the Cu wiring layer 832; a resin layer forming process, forming the resin layer 850 to seal the semiconductor element 20; a first deleting process, deleting the support substrate 800 and the temporary fixing layer 810; and a second deleting process, deleting the sacrificial film 811. In the conductive layer forming process, the conductive layer 831 enters the through hole 43 and contacts the sacrificial film 811.

According to the configuration, after forming the organic film 840 on the sacrificial film 811 made of Ti and forming the conductive layer 831 on the organic film 840, since the conductive layer 831 is Ti-free, deleting of the conductive layer 831 together with the sacrificial layer 811 can be inhibited when the sacrificial film 811 is deleted from the organic film 840. Thus, unlike the semiconductor device 10X of the comparison example, an intermediary (the back surface side Cu wiring layer 33X of the semiconductor device 10X) needed in the comparison example for preventing the deleting of the conductive layer 831 (31) while the sacrificial layer 811 is deleted is not needed between the sacrificial film 811 and the conductive layer 831 (31). Therefore, the step of forming the intermediary (the first wiring layer forming process in the manufacturing method for the semiconductor device 10) can be omitted to simplify the manufacturing steps of the semiconductor device 10. Therefore, manufacturing costs of the semiconductor device 10 can be reduced.

(4) The thickness of the conductive layer 831 (31) is between 400 nm and 600 nm. According to the configuration, the thickness of the conductive layer 831 (31) is set to be 400 nm or more, and non-uniform thickness of the Cu wiring layer 832 when the Cu wiring layer 832 is formed can be suppressed.

(5) In the semiconductor element 20, a plurality of element electrodes 24 are provided on the element main surface 21 facing the Cu wiring layer 32 in the z direction. The element electrodes 24 are individually bonded with the plurality of Cu wiring layers 32 by the solder layer SD. In the direction orthogonal to the z direction, the element electrodes 24 are bonded to portions different from the recessed portion 32a formed in the portion that enters the through hole 43.

According to the configuration, the recessed portion 32a of the Cu wiring layer 32 forming the portion that enters the through hole 43 is not arranged opposite to each of the element electrodes 24 in the z direction. That is to say, each of the element electrodes 24 is bonded to the portion of the Cu wiring layer 32 that becomes a plane orthogonal to the z direction. Thus, the semiconductor element 20 can be easily mounted on the Cu wiring layer 32.

### VARIATION EXAMPLES

The embodiments are examples of means to obtain the semiconductor device and the manufacturing method for a semiconductor device related to the disclosure, and are not to be construed as limitations to the means. The semiconductor device and the manufacturing method for a semiconductor device related to the disclosure can adopt means different from those described in the exemplary embodiments. An example thereof is obtained by replacing, changing, or omitting a part of the configuration of the embodiment, or a form obtained by adding a new configuration to the embodiment. Moreover, given that no technical contradiction is resulted, the following variation examples may be used in combination. In the variation examples below, parts that are common with the embodiment describe above are denoted by the same numerals and symbols, and the related description is omitted.

In the embodiment, when the configuration is observed in the z direction, the overlapping position of each of the wires 30 with the semiconductor element 20 extends to outside relative to the semiconductor element 20, and the plurality of external terminals 60 are arranged outside relative to the semiconductor element 20. However, the configuration of the wires 30 or the arrangement positions of the plurality of external terminals 60 are not limited to the examples above. For example, it may also be set that, when observed in the z direction, the configuration may be an FIWLP in which the plurality of exterior terminals 60 are arranged at positions overlapping with the semiconductor element 20. In this case, when observed in the z direction, the wire 30 is formed at a position overlapping with the semiconductor element 20. That is to say, when observed in the z direction, the wire 30 does not extend to outside relative to the semiconductor element 20.

In this embodiment, when the configuration is observed in the z direction, although the exposed conductive portion 31a of the wire 30 is arranged outside relative to the element electrodes 24 of the semiconductor element 20, it should be noted that the arrangement relation of the exposed conductive portion 31a and the element electrodes 24 is not limited to such example. For example, when observed in the z direction, the exposed conductive portion 31a is arranged inside relative to the element electrodes 24. In other words, the element electrodes 24 may also be arranged outside relative to the exposed conductive portion 31a.

In the embodiment, although the plurality of element electrodes formed on the element main surface 21 of the semiconductor element 20 are bonded by mounting on the flip-chip of the wire 30 by the solder layer SD, the connection means for the semiconductor element 20 and the wire 30 is not limited to such example. For example, the semiconductor element 20 and the wire 30 may also be connected by a lead wire. In an example, a plurality of electrode pads are formed on the element back surface 22 of the semiconductor element 20. For example, a heat dissipation plate formed on the organic film 40 is mounted on the element main surface 21 of the semiconductor element 20. The heat dissipation plate is, for example, exposed from the organic film 40 (the device back surface 12) in the z direction. That is to say, the heat dissipation plate forms a part of the device back surface 12. The lead wire is formed to connect the plurality of electrode pads and the wire 30, by, for example, lead wire bonding.

In this case, the element mounting process in the manufacturing method for the semiconductor device 10 includes: an element fixing process, fixing the semiconductor element 20 on the heat dissipation plate by, for example, an adhesive; and a connection process, forming a lead wire connecting the electrode pads of the semiconductor element 20 and the wire 30 (the Cu wiring layer 32). A lead wire bonding device is used to form the lead wire in the connection process.

In the embodiment, the number of the element electrodes 24 of the semiconductor element 20 and the arrangement pattern of the element electrodes 24 of the semiconductor element 20 can be respectively modified as desired. The number and arrangement pattern of the element electrodes 24 are set according to, for example, the circuit configuration of the semiconductor element 20.

In the embodiment, the number and arrangement pattern of the wires 30 can be respectively modified as desired. In one example, the number of wires 30 may also be set according to the number of the element electrodes 24 of the semiconductor element 20.

In the embodiment, the exposed conductive portion 31a is formed across the entire opening in the through hole 43 of the organic film 40 on the side of the film back surface 42; however, the disclosure is not limited to the example above. For example, the exposed conductive portion 31a may also be shaped as a frame contacting an outer periphery of the opening of the through hole of the organic film 40 on the side of the film back surface 42. In this case, the Cu wiring layer 32 enters the frame-shaped exposed conductive portion 31a. Accordingly, the Cu wiring layer 32 has an exposed surface exposed from the organic film 40 by entering the through hole 43. The exposed surface of the Cu wiring layer 32 is exposed from the film back surface 42 of the organic film, and is contact with the external terminal 60. In this case, the external terminal 60 is in contact with both the conductive layer 31 and the Cu wiring layer 32.

According to such configuration, because of the conductive layer 31 intermediates between the Cu wiring layer 32 and the organic film 40, the Cu wiring layer 32 and the organic film 40 are not in direct contact, and peeling off of the wire 30 from the organic film 40 can be inhibited. Moreover, effects of (1) and (3) of the embodiments can be achieved.

In the embodiment, the external terminal 60 is formed by a layered structure of a Ni layer, a Pd layer and a Au layer; however, the disclosure is not limited to the example above, and the external terminal 60 may also be formed by a substantially semi-spherical solder bump.

In the embodiment, the number of the semiconductor element 20 can be modified as desired. For example, the semiconductor device 10 may also include a plurality of semiconductor elements 20.

In the embodiment, the semiconductor device 10 may include the semiconductor element 20, and a specific element different from the semiconductor element 20. The specific element may be a semiconductor element having a function different from that of the semiconductor element 20, or may be an element other than a semiconductor element, such as a coil or a resistor. In one example, the specific element is electrically connected to the semiconductor element 20. In this case, for example, the specific element is mounted to the wire 30. The specific element sealed by the sealing resin 50.

### (Notes)

The technical concepts that are conceivable based on the embodiments and the variation examples are recoded in the description below.

(Note 1) A semiconductor device, including: an organic film, being electrically insulative and penetrated by a through hole in a thickness direction; a conductive layer, formed on the organic film and made of a copper (Cu)-based and titanium (Ti)-free alloy; a Cu wiring layer, formed on the conductive layer; a semiconductor element, mounted on the Cu wiring layer; a sealing resin, sealing the semiconductor element; and an external terminal, connected to the conductive layer, wherein the conductive layer includes an exposed conductive portion entering the through hole and exposed from the organic film, and the external terminal is in contact with the exposed conductive portion.

(Note 2) The semiconductor device according to note 1, wherein the organic film has a film main surface on which the conductive layer is formed, and a film back surface facing an opposite side of the film main surface in the thickness direction, the exposed conductive portion is exposed from the film back surface by entering the through hole, and the exposed surface of the exposed conductive portion is flush with the film back surface.

(Note 3) The semiconductor device according to note 1, further including a specific element different from the semiconductor element, wherein the specific element is sealed by the sealing resin.

(Note 4) A semiconductor device, including: an organic film, being electrically insulative and penetrated by a through hole in a thickness direction; a conductive layer, formed on the organic film and made of a copper (Cu)-based and titanium (Ti)-free alloy; a Cu wiring layer, formed on the conductive layer; an element, mounted on the Cu wiring layer; a sealing resin, sealing the element; and an external terminal, connected to the conductive layer, wherein the conductive layer includes an exposed conductive portion entering the through hole and exposed from the organic film, and the external terminal is in contact with the exposed conductive portion.

1. A semiconductor device, comprising:
an organic film, being electrically insulative and penetrated by a through hole in a thickness direction;
a conductive layer, formed on the organic film and made of a copper (Cu)-based and titanium (Ti)-free alloy;
a Cu wiring layer, formed on the conductive layer;
a semiconductor element, mounted on the Cu wiring layer;
a sealing resin, sealing the semiconductor element; and
an external terminal, connected to the conductive layer, wherein the conductive layer includes an exposed conductive portion entering the through hole and exposed from the organic film, and the external terminal is in contact with the exposed conductive portion.

2. The semiconductor device of claim 1, wherein the organic film has a film main surface on which the conductive layer is formed, and a film back surface facing an opposite side of the film main surface in the thickness direction, and wherein the exposed conductive portion is exposed from the film back surface by entering the through hole.

3. The semiconductor device of claim 1, wherein the conductive layer is made of an alloy containing Cu as a main component and any of aluminum (Al), magnesium (Mg) and manganese (Mn).

4. The semiconductor device of claim 2, wherein the conductive layer is made of an alloy containing Cu as a main component and any of aluminum (Al), magnesium (Mg) and manganese (Mn).

5. The semiconductor device of claim 1, wherein
the semiconductor element includes an element main surface facing the Cu wiring layer in the thickness direction and at least one element electrode formed on the element main surface,
the at least one element electrode is bonded to the Cu wiring layer by a conductive bonding material, and
the exposed conductive portion is arranged outside the semiconductor element in a direction orthogonal to the thickness direction.

6. The semiconductor device of claim 2, wherein
the semiconductor element includes an element main surface facing the Cu wiring layer in the thickness direction and at least one element electrode formed on the element main surface,
the at least one element electrode is bonded to the Cu wiring layer by a conductive bonding material, and
the exposed conductive portion is arranged outside the semiconductor element in a direction orthogonal to the thickness direction.

7. The semiconductor device of claim 3, wherein
the semiconductor element includes an element main surface facing the Cu wiring layer in the thickness direction and at least one element electrode formed on the element main surface,
the at least one element electrode is bonded to the Cu wiring layer by a conductive bonding material, and
the exposed conductive portion is arranged outside the semiconductor element in a direction orthogonal to the thickness direction.

8. The semiconductor device of claim 4, wherein
the semiconductor element includes an element main surface facing the Cu wiring layer in the thickness direction and at least one element electrode formed on the element main surface,
the at least one element electrode is bonded to the Cu wiring layer by a conductive bonding material, and
the exposed conductive portion is arranged outside the semiconductor element in a direction orthogonal to the thickness direction.

9. A method for forming a semiconductor device, comprising:
a preparatory process, forming a temporary fixing layer on a support substrate and forming a sacrificial film made of Ti on the temporary fixing layer;
an organic film forming process, forming an electrically insulative organic film in which a through hole penetrating in a thickness direction on the sacrificial film;
a conductive layer forming process, forming a conductive layer made of a copper (Cu)-based and titanium (Ti)-free alloy on each of the organic film and the sacrificial film exposed from the through hole;
a wiring layer forming process, forming a Cu wiring layer on the conductive layer;
an element mounting process, electrically connecting a semiconductor element to the Cu wiring layer;
a resin layer forming process, forming a resin layer to seal the semiconductor element;
a first deleting process, deleting the support substrate and the temporary fixing layer; and
a second deleting process, deleting the sacrificial film, wherein in the conductive layer forming process, the conductive layer enters the through hole and contacts the sacrificial film.

10. The method of claim 9, wherein the conductive layer is made of an alloy containing Cu as a main component and any of aluminum (Al), magnesium (Mg) and manganese (Mn).

11. The method of claim 9, after the second deleting process, further comprising a terminal forming process, forming an external terminal on an exposed conductive portion exposed from the organic film by entering the through hole of the conductive layer, wherein the external terminal is formed by electroless plating.

12. The method of claim 10, after the second deleting process, further comprising a terminal forming process, forming an external terminal on an exposed conductive portion exposed from the organic film by entering the through hole of the conductive layer, wherein the external terminal is formed by electroless plating.

13. The method of claim 9, wherein a thickness of the conductive layer is between 400 nanometers (nm) and 600 nm.

14. The method of claim 10, wherein a thickness of the conductive layer is between 400 nm and 600 nm.

15. The method of claim 11, wherein a thickness of the conductive layer is between 400 nm and 600 nm.

16. The method of claim 12, wherein a thickness of the conductive layer is between 400 nm and 600 nm.
